(19) United States
(12) Patent Application Publication
(10) Pub. No.: US 2011/0155208 A1
(43) Pub. Date: Jun. 30, 2011

(54) SEMICONDUCTOR HETEROJUNCTION PHOTOVOLTAIC SOLAR CELL WITH A CHARGE BLOCKING LAYER

(76) Inventor: Michael Wang, Sunnyvale, CA (US)

(21) Appl. No.: 12/999,048

(22) PCT Filed: Jun. 25, 2009
(86) PCT No.: PCT/US09/48727

§ 371 Date: Mar. 21, 2011

Related U.S. Application Data
(60) Provisional application No. 61/075,730, filed on Jun. 25, 2008.

(51) Int. Cl. H01L 31/042; H01L 31/18; H01L 31/06

(52) U.S. Cl. 136/244; 438/84; 136/255; 257/E31.015

(57) ABSTRACT

A heterojunction photovoltaic device comprises a chemically-doped n-type semiconductor layer, a charge-blocking layer that can have a compositionally graded configuration, and a chemically-doped p-type semiconductor layer. The charge-blocking layer can significantly reduce interfacial recombination of electrons and holes, increase open circuit voltage (Voc), and increase overall photovoltaic device efficiency.

### CROSS REFERENCE

The application claims the benefit of U.S. Provisional Patent Application No. 61/075,730, filed Jun. 25, 2008, which is entirely incorporated herein by reference.

### FIELD OF THE INVENTION

The invention generally relates to photovoltaic cells, more particularly to photovoltaic cells having charge-blocking layers.

### BACKGROUND OF THE INVENTION

A photovoltaic cell (also “solar cell” herein) is able to absorb radiant light energy and convert it directly into electrical energy. Some photovoltaic (“PV”) cells are employed as sensors in cameras to obtain an electrical signal or a measure of the ambient light. Other photovoltaic cells are used to generate electrical power. Photovoltaic cells can be used to power electrical equipment for which it has otherwise proved difficult or inconvenient to provide a source of continuous electrical energy.

An individual photovoltaic cell has a distinct spectrum of light to which it is responsive. The particular spectrum of light to which a photovoltaic cell is sensitive is primarily a function of the material forming the cell. Photovoltaic cells that are sensitive to light energy emitted by the sun can be referred to as solar cells.

Individually, any given photovoltaic cell is capable of generating only a relatively small amount of power. Consequently, for most power generation applications, multiple photovoltaic cells are connected together in series into a single unit, which can be referred to as an array. When a photovoltaic cell array, such as a solar cell array, produces electricity, the electricity can be directed to various locations, such as, e.g., a home or business, or a power grid (e.g., smart grid).

When electromagnetic radiation of an appropriate energy is incident upon a PV cell, a photon is absorbed to form an electron-hole pair. An electron, once generated, is conducted away, typically by conduction to an electrode in electrical contact with an absorber region of the PV cell, but there is a finite length of time during which the electron remains separated from a hole. Recombination lifetime (also “carrier lifetime” herein) can refer to time it takes an electron to recombine with a hole. The longer the recombination lifetime, the more time (on average) an electron has to travel to an electrode an be conducted away from the PV cell. Thus, in order to obtain high PV cell efficiencies, longer recombination lifetimes are desired.

One problem associated with photovoltaic (“PV”) cells is the recombination of electrons and holes in a photovoltaic device. Recombination can occur at various locations of the photovoltaic device, such as, e.g., between the electrodes and the p-n junction of the PV device, at the heterojunction interfaces within the p-n junction of the PV device, and in the bulk structure of the PV device (i.e., bulk recombination). Another problem that can cause an unwanted increase in current is electrical shorting due to defects or nonuniformities in the substrate and/or the one or more films of the photovoltaic device.

The recombination of electrons and holes in a photovoltaic device can decrease the efficiency of the photovoltaic device. Accordingly, there is a need in the art for methods and structures that minimize, if not eliminate, the recombination of electrons and holes in a PV device.

### SUMMARY OF THE INVENTION

The invention provides methods and systems for enabling high-efficiency solar cells, including multi-junction photovoltaic or solar cells. Various aspects of the invention can be utilized to significantly reduce or substantially eliminate interfacial recombination and/or increasing Voc (open circuit voltage) in solar cells with heterojunction interfaces.

In one aspect of the invention, highly efficient photovoltaic cells are provided with charge-blocking layers. Other aspects of the invention provide methods of manufacturing or forming the heterojunction solar cells described herein.

One aspect of the invention provides a photovoltaic (“PV”) cell comprising a charge-blocking layer between a first layer and a second layer, the first layer being compositionally different from the second layer, wherein the first layer is doped p-type and the second layer is doped n-type. In an embodiment, the charge-blocking layer is configured to prevent the recombination of electrons and holes by spatially separating regions of electron accumulation from regions of hole accumulation.

Another embodiment of the invention provides a PV cell comprising a first layer including cadmium and selenium, wherein the first layer is chemically doped n-type. The PV cell further comprises a second over the first layer, the second layer comprising two or more of cadmium, magnesium, selenium, tellurium and zinc. In a preferable embodiment, two or more elements of the second layer are in a graded configuration. In a preferable embodiment, the second layer is a charge-blocking (also “blocking” herein) layer. The PV cell also comprises a third layer disposed over the second layer, wherein the third layer is chemically doped p-type. The third layer includes one or more of cadmium and zinc and one or more of selenium and sulfur. In an embodiment, the PV cell includes a substrate below the first layer, wherein the substrate is in electrical contact with a first electrode. In such a case, the PV device can include a transparent conductive oxide (TCO) layer over the third layer. A first electrode is in contact with the substrate; a second electrode is disposed over the third layer. In another embodiment, the PV cell includes a substrate over the third layer. In such a case, the PV device can include a TCO layer below the first layer.

Another embodiment of the invention provides a photovoltaic cell comprising a charge-blocking layer having two or more of cadmium (Cd), magnesium (Mg), selenium (Se), tellurium (Te) and zinc (Zn), the charge-blocking layer disposed between a first layer and a second layer, the first layer comprising Te and one or more of Cd and Zn, and the second layer comprising one or more of Cd and Zn and one or more of Se and sulfur (S). In an embodiment, the first layer comprises a p-type chemical dopant and the second layer comprising an n-type chemical dopant. The charge-blocking layer is configured to prevent the recombination of electrons and holes by spatially separating regions of electron accumulation from regions of hole accumulation.

Another embodiment of the invention provides a photovoltaic device comprising a first layer including tellurium (Te) and one or more of cadmium (Cd) and zinc (Zn). The PV device further comprises a second layer over the first layer, the second layer comprising two or more of Cd, magnesium (Mg), selenium (Se), Te and Zn in a compositionally-graded configuration. The PV device also comprises a third layer over the second layer, the third layer comprising one or more of cadmium (Cd) and zinc (Zn) and one or more of Se and sulfur (S).

Another embodiment of the invention provides a PV array comprising PV cells (or devices) of various embodiments of the invention.

Another aspect of the invention provides methods for forming a photovoltaic device, comprising forming a first layer including tellurium (Te) and one or more of cadmium (Cd) and zinc (Zn); forming a second layer comprising two or more of Cd, magnesium (Mg), selenium (Se), Te and Zn in a compositionally-graded configuration; and forming a third layer comprising one or more of Cd and Zn and one or more of Se and Sulfur (S). In an embodiment, the first layer is doped with a p-type chemical dopant. In another embodiment, the third layer is doped with an n-type chemical dopant. In an embodiment, the first layer is adjacent the second layer.

In one embodiment, forming the first layer comes before forming the third layer (i.e., the first layer is formed before the third layer). In another embodiment, forming the first layer comes after forming the third layer (i.e., the first layer is formed after the third layer).

Additional aspects and embodiments of the present disclosure will become readily apparent to those skilled in this art from the following detailed description, wherein only exemplary embodiments of the present disclosure are shown and described, simply by way of illustration of the best mode contemplated for carrying out the present disclosure. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity. A better understanding of the features and advantages of the present invention will be obtained by reference to the following detailed description that sets forth illustrative embodiments, in which the principles of the invention are utilized, and the accompanying drawings of which:

FIG. 1A shows a heterojunction photovoltaic (“PV”) device comprising a charge-blocking layer, in accordance with an embodiment of the invention;

FIG. 1B illustrates a series of steps that can be used to form the PV device of FIG. 1A, in accordance with an embodiment of the invention;

FIG. 1C shows an energy diagram (valence band, bottom, and conduction band, top) for the heterojunction PV device of FIG. 1A, i.e., a device comprising an n-type CdSe layer, a graded CdₓZn₁₋ₓSe blocking layer, and a p-type ZnTe layer, in accordance with an embodiment of the invention;

FIG. 1D schematically illustrates a CdSe/CIGS two-terminal PV cell incorporating a graded blocking layer, in accordance with an embodiment of the invention;

FIG. 2 is a schematic illustration of a PV cell comprising n-CdSe/p-ZnTe, but not having a graded blocking layer, in accordance with an embodiment of the invention;

FIG. 3 is a schematic illustration of a PV cell having a graded blocking layer that produces a spatial separation of regions for electron and hole charge accumulation, in accordance with an embodiment of the invention;

FIG. 4 shows a current-voltage (IV) plot for a baseline case (i.e., a PV cell without a graded blocking layer), in accordance with an embodiment of the invention;

FIG. 5 shows (a) conduction and valence band plots (energy diagram), (b) carrier density plots and (c) current density plots for a baseline PV device at 0.65 V forward bias, in accordance with an embodiment of the invention;

FIG. 6 shows an IV curve for an n-CdSe/graded blocking layer/p-ZnTe PV device, in accordance with an embodiment of the invention;

FIG. 7 a shows (a) conduction and valence band plots, (b) carrier density plots and (c) current density plots for an n-CdSe/graded blocking layer/p-ZnTe PV device at about 0.65 V forward bias, in accordance with an embodiment of the invention;

FIG. 8 shows (a) conduction and valence band plots (energy diagram), (b) carrier density plots and (c) current density plots for a PV device incorporating a graded blocking layer at near Voc conditions of about 1.25 V, in accordance with an embodiment of the invention;

FIG. 9 shows Voc as a function of interfacial defect density for a PV device having a graded blocking layer (top) and a PV device without a graded blocking layer (bottom), in accordance with an embodiment of the invention; and

FIG. 10 shows the cell efficiency as a function of interfacial defect density for a PV device having a graded blocking layer (top) and a PV device without a graded blocking layer (bottom), in accordance with an embodiment of the invention.

### DETAILED DESCRIPTION OF INVENTION

While preferable embodiments of the invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein can be employed in practicing the invention.

A preferable embodiment of the invention provides a heterojunction photovoltaic solar cell device that includes the following components: i) an n-type semiconductor layer; ii) a charge-blocking layer; and iii) a p-type semiconductor layer. At least some elements defining the charge-blocking layer can be in a compositionally graded configuration. The n-type semiconductor layer forms a chemically doped n-type (also “n-doped” herein) side of the PV cell; the p-type semiconductor layer forms the chemically doped p-type (also “p-doped” herein) side of the PV cell.

PV devices of embodiments of the invention can minimize, if not eliminate, problems associated with electron-hole recombination within a PV device. PV devices of preferable embodiments offer increased recombination lifetimes, while permitting flexibility in the design and implementation of PV cells.

The charge-blocking layer of preferable embodiments can ensure or at least facilitate the spatial separation of electrons and holes in order to avoid or significantly reduce interfacial recombination. The blocking layer of preferable embodiments can provide or enable a larger operating voltage for overall improved photovoltaic device efficiency. The blocking layer can be compositionally graded in order to provide a smooth compositional transition from one interface to another. In some embodiments, the blocking layer can be graded in a stepwise fashion rather than smoothly graded. A graded blocking layer can minimize interfacial defects that can contribute to interfacial recombination. Compositions of the graded blocking layer can vary through the thickness of the charge-blocking layer. As an illustrative example, in a CdSe/Graded CdₓZn₁₋ₓSe/ZnTe device, the Zn concentration, can be set to a low value (e.g., x in the range of about 0 and about 0.3) at the CdSe/Graded CdₓZn₁₋ₓSe interface, and grading up to a high Zn, low Cd concentration at the Graded CdₓZn₁₋ₓSe/ZnTe interface (e.g., x in the range of about 0.5 and about 1.0).

When reference is made to a layer having an element, such as cadmium (Cd), Zinc (Zn) or tellurium (Te), it will be appreciated that the layer comprises atoms of that element. For example, a layer comprising Cd is formed, at least in part, of Cd atoms. As another example, a layer comprising Cd, Zn and selenium (Se) is formed, at least in part, of Cd, Zn and Se atoms. In at least some cases, the composition of such a layer can be CdZnSe. The CdZnSe layer can be compositionally graded in two or more of the elements. As yet another example, a layer comprising Te and one or more of Cd and Zn is formed, at least in part, of Te atoms and Cd atoms and/or Zn atoms. In at least some cases, the composition of such a layer can be CdTe, ZnTe, or CdZnTe.

### PV Devices Having Charge Blocking Layers

In one aspect of the invention, a PV device comprises a first semiconductor layer over a substrate; a second semiconductor layer over the first semiconductor layer, wherein the second semiconductor layer is a charge-blocking layer; and a third semiconductor layer over the second semiconductor layer. In an embodiment, the first semiconductor layer is chemically doped with a p-type dopant (i.e., the first semiconductor layer comprises a p-type dopant). In another embodiment, the third semiconductor layer is chemically doped with an n-type dopant (i.e., the third semiconductor layer comprises an n-type dopant). In an embodiment, the first layer and the third layer are compositionally different (or dissimilar). In an embodiment, the charge-blocking layer is configured to prevent the recombination of electrons and holes—formed upon exposure of the photovoltaic cell to photons—by spatially separating regions of electron accumulation from regions of hole accumulation. In an embodiment, regions of hole accumulation are in the first (p-type) layer and regions of electron accumulation are in the third (n-type) layer. In an embodiment, the first layer is disposed over a substrate. In an alternative embodiment, the third layer is disposed below the substrate.

In embodiments of the invention, the first layer comprises tellurium (Te) and one or more of zinc (Zn) and cadmium (Cd); the second layer comprises two or more of Cd, magnesium (Mg), selenium (Se), Te and Zn; and the third layer comprises one or more of Cd and Zn and one or more of Se and sulfur (S). The second layer can be compositionally graded in two or more of the elements comprising the second layer. In an embodiment, the first layer is doped with a p-type dopant and the third layer is doped with an n-type dopant.

In an embodiment, the first layer is formed of Te and Zn; the second layer is formed of Cd, Zn and Se, and it is graded in Cd and Zn; and the third layer is formed of Cd and Se. In an alternative embodiment, the second layer is formed of Cd, Mg and Se, and it is graded in Cd and Mg. In a preferable embodiment, the second layer is a charge-blocking layer configured to prevent the recombination of electrons and holes.

Reference will now be made to the figures, wherein like numerals refer to like parts throughout. It will be appreciated that the figures are not necessarily drawn to scale.

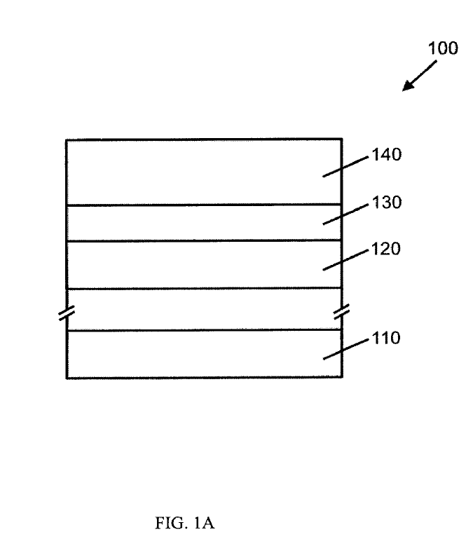

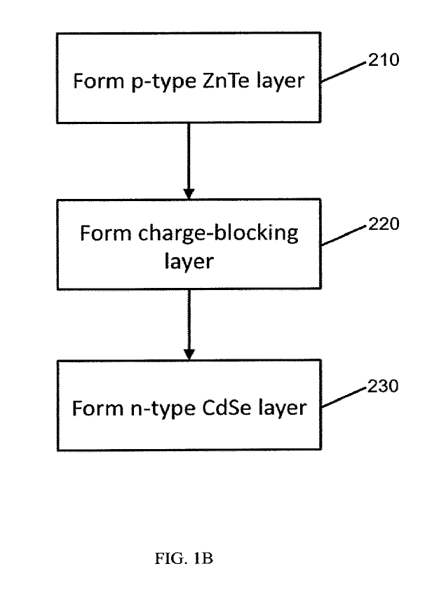

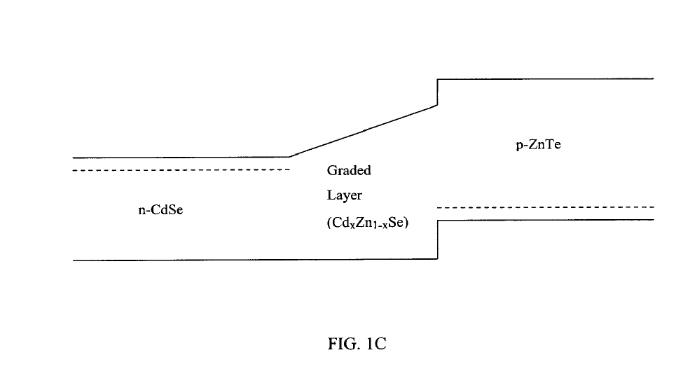

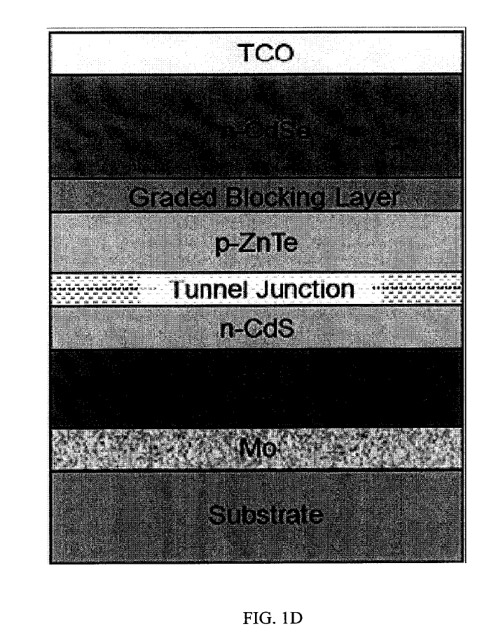

With reference to FIG. 1A, a photovoltaic structure 100 is provided in accordance with an embodiment of the invention is shown. The photovoltaic structure 100 comprises, from bottom to top, a substrate 110, a p-type semiconductor layer 120, a charge-blocking layer 130 and an n-type semiconductor layer 140. The PV structure 100 can include other layers between the substrate 110 and the p-type semiconductor layer 120 (as illustrated by the broken lines), as well as additional layers over the n-type semiconductor layer 140. For example, the PV structure may include a CIGS cell (see FIG. 1C). During operation of the PV device 100, photons (light) enter the PV device 100 from the top of the device 100, i.e., light first enters the n-type semiconductor layer 140 before entering the charge-blocking layer 130.

With continued reference to FIG. 1A, in an embodiment, the n-type semiconductor layer 140 can comprise n-CdSe (i.e., CdSe doped with an n-type chemical dopant); the charge-blocking layer 130 can comprise graded CdₓZn₁₋ₓSe, wherein ‘x’ is a number between 0 and 1; and the p-type semiconductor layer 120 can comprise p-ZnTe (i.e., ZnTe doped with a p-type chemical dopant). The substrate 110 can be formed of a dielectric material (e.g., glass), stainless steel, titanium, a flexible polymeric material, or any semiconductor material, such as single crystal Si, polycrystalline Si, or a Group III-V semiconductor, such as, e.g., GaSb or GaAs. In one embodiment, the substrate is formed of stainless steel sheets or rolls. In another embodiment, the substrate is formed of polymeric sheets or rolls. The substrate can be of any shape and thickness suitable for a desirable application of the PV device.

In some embodiments, the relative ratios of various elemental species within each of the material layers can be varied as desired to achieve optimum device performance. In an embodiment, the ratio of elemental species in the p-type semiconductor layer 120 and the n-type semiconductor layer 140 is one-to-one.

With continued reference to FIG. 1A, in an embodiment, the p-type semiconductor layer 120 can have a thickness between about 50 nanometers (“nm”) and 4000 nm, or between about 50 nm and 2000 nm, or between about 50 nm and 500 nm; the charge-blocking layer 130 can have a thickness between about 10 nm and 300 nm, or between about 15 nm and 150 nm, or between about 20 nm and 50 nm; and the n-type semiconductor layer 140 can have a thickness between about 50 nm and 4000 nm, or between about 500 nm and 3000 nm, or between about 2000 nm and 3000 nm.

N-type doping (also “chemical doping” herein) can be achieved with the aid of, e.g., chlorine (Cl), Iodine (I), or bromine (Br) atoms, either during formation of various material layers or following formation of various material layers. P-type doping can be achieved with the aid of, e.g., nitrogen (N), phosphorous (P), arsenic (As), or antimony (Sb) atoms.

In an alternative embodiment, the charge-blocking layer can be formed of CdMgSe and graded in Cd and Mg, i.e., CdₓMg₁₋ₓSe, wherein ‘x’ is a number between 0 and 1.

In an alternative embodiment, the doping configuration of the layers of FIG. 1A can be reversed. In such a case, the PV device can include an n-type semiconductor layer over the substrate; a charge-blocking layer over the n-type semiconductor layer; and a p-type semiconductor layer over the charge-blocking layer.

The charge blocking layers of various embodiments provide solar cells that allow particular engineering of the band gap, valence band offsets, and conduction band offsets for various applications. Accordingly, electron and hole accumulations occur on either side of the blocking layer (e.g., CdZnSe blocking layer), that results in charge separation by roughly the thickness of the blocking layer. This separation can be sufficient to prevent interfacial recombination. In addition, with the desired engineering or modification of the blocking layer, either through grading of composition or the selection of a specific composition, the carrier injection for either holes or electrons can be selectively inhibited such that the device turn-on voltage can be set so as to achieve solar cell efficiencies that are relatively higher that those achievable using prior art solar cells. In an embodiment, the device turn-on voltage can be increased to achieve relatively high solar cell efficiencies. In addition, for certain solar cell applications, it can be preferable to engineer or design the blocking layer in accordance with the invention so that holes and electrons generated in the absorber layer or region are able to be transported out of the device.

FIG. 1B illustrates a series of steps that can be employed to form the PV cell of FIG. 1A. First, in step 210 a p-ZnTe layer is formed over a substrate. The p-ZnTe layer can be formed using any deposition technique known in the art (see below). As an example, the p-ZnTe layer can be formed via co-evaporation using fluxes of Zn and Te. P-type doping of the ZnTe layer can be achieved either during deposition of the ZnTe layer or following formation of the ZnTe layer.

Next, in step 220 a CdZnSe charge-blocking layer, compositionally graded in Cd and Zn, is formed. Grading can be accomplished by a decreasing amount of Zn in going from the p-ZnTe side of the device to the n-CdSe side of the device. The relative composition of Se is kept constant. As the composition of Zn is decreased, the composition of Cd is increased. Formed in such manner, at a first interface adjacent the ZnTe layer, the charge-blocking layer comprises substantially all ZnSe (i.e., there is substantially little Cd); at a second interface adjacent the CdSe layer, the charge-blocking layer comprises substantially all CdSe (i.e., there is substantially little Zn).

Next, in step 230 an n-CdSe layer is formed over the charge-blocking layer. The n-CdSe layer can be formed using any deposition technique known in the art (see below). As an example, the ZnTe layer can be formed via co-evaporation using fluxes of Cd and Se precursors. N-type doping of the CdSe layer can be achieved either during deposition of the CdSe layer or following formation of the CdSe layer.

Following formation of one or more of the p-ZnTe layer, charge-blocking layer and n-CdSe layer, the substrate can be annealed for a predetermined period of time. Annealing can aid in curing defects formed during deposition of one or more layers of the PV device.

In alternative embodiment (now shown), the steps used in forming the PV device of FIG. 1A are reversed. In such a case, the n-type CdSe layer is formed first over, e.g., a TCO layer or a substrate. Next, the graded charge-blocking layer is formed over the n-type CdSe layer. Next, the p-type ZnTe layer is formed over the graded charge-blocking layer.

The p-type ZnTe layer, charge-blocking layer, and n-type CdSe layer can be formed using any technique known in the art, such as, for example, chemical vapor deposition (CVD), atomic layer deposition (ALD), physical vapor deposition (PVD), electroplating, co-evaporation, sputtering, inkjet printing techniques, sintering, plasma-enhanced CVD (PECVD) or plasma-enhanced ALD (PEALD), molecular beam epitaxy, or a technique that combines two or more of these methods.

FIG. 1C illustrates an energy diagram of a heterojunction photovoltaic solar cell comprising CdₓZn₁₋ₓSe for a blocking layer that can be used, for example, in the solar cell of FIG. 1A (i.e., a solar cell formed of an n-type CdSe layer, a graded CdₓZn₁₋ₓSe blocking layer, and a p-type ZnTe layer), in accordance with a preferable embodiment of the invention. The discontinuity in the energy band diagram (valance and conduction bands) at the interface between the blocking layer and the p-type ZnTe layer substantially prevents electron-hole recombination, thereby providing for enhanced PV device efficiencies in relation to other prior art solar cells.

FIG. 1D illustrates a two-terminal PV device, in accordance with an embodiment of the invention. The PV device comprises an upper cell over a lower cell, the upper cell comprising a CdSe layer over a charge-blocking layer, which is in turn disposed over a ZnTe layer; the lower cell comprising a copper indium gallium (di) selenide (“CIGS”) cell. The PV device comprises, from bottom to top, a substrate, a molybdenum (Mo) layer, a CIGS layer (or cell), an n-type CdS layer, a tunnel junction, a p-type ZnTe layer, a charge-blocking layer, an n-type CdSe layer, and a transparent conducting oxide (“TCO”) layer. The tunnel junction can comprise a highly-doped ZnTe/CdSe bilayer. The PV device can comprise additional layers. For example, the PV device can comprise an electrode in electrical contact with the substrate and en electrode in electrical contact with the TCO layer.

In an embodiment, the n-type CdS layer adjacent the CIGS cell can be replaced by a lower band gap material, such as CdSe, to give more flexibility in manufacturing and device optimization.

According to other aspects of the invention, the blocking layer described herein can be structured in several ways. For example, many of the possible manifestations of the invention include grading of the blocking layer to reduce interfacial trap densities at one of the two interfaces, while some use a blocking layer that is not graded. Alternative embodiments of the invention include, but are not limited to, PV devices comprising the following structures: i) n-CdSe/graded CdₓZn₁₋ₓSe/p-ZnTe; ii) n-CdSe/graded MgₓCd₁₋ₓSe_{y}Te_{1-y}/p-ZnTe; iii) n-CdSe/graded MgₓCd₁₋ₓSe_{y}Te_{1-y}/p-CdZnTe; iv) n-CdₓZn₁₋ₓSe/graded MgₓCd₁₋ₓSe_{y}Te_{1-y}/p-CdZnTe; v) n-CdSe/Graded MgₓCd₁₋ₓSe/p-ZnTe; vi) n-CdSe/ZnSe blocking layer/p-ZnTe and vii) n-CdS/Graded ZnₓCd₁₋ₓS/p-CdTe.

Although in the above examples Group II-VI wide semiconductors have been used, it will be appreciated that other photovoltaic semiconductors, such as, for example, Group III-V or Group IV semiconductors, can be used.

Furthermore, for embodiments of the invention in which Mg is used in the blocking layer, it is possible to use Te in the ternary (three types of atoms)/quaternary (four types of atoms) blocking layer in order to raise the valence band edge. Unlike devices such as light emitting diodes (LEDs) where the minority carrier transportation is relatively unimportant, that is not the case usually for solar cells. More specifically, if or when there is a barrier to minority carrier transportation, the performance of the solar device can be negatively impacted. Moreover, due to the slight lowering of the valence band edge in ternaries such as MgₓCd₁₋ₓSe, there can be additional benefits to device performance with the addition of some Te to the blocking layer. In this case the Te replaces Se with a resulting quaternary compound of MgₓCd₁₋ₓSe_{y}Te_{1-y}. In addition, if the valence band edge position becomes a challenge for the extraction of minority carriers, deeper energy states can be introduced at the interface in order to enable tunneling and extraction of the carriers.

While single PV devices (or cells) have been shown, it will be appreciated that a PV device can comprise multiple PV cells. For example, PV devices of embodiments of the invention can be arranged in a parallel or series fashion to form PV arrays.

PV cells of embodiments of the invention can be incorporated in devices having various form factors. As an example, PV cells (or devices) of embodiments of the invention can be incorporated in flat-panel PV devices. As another example, PV devices of embodiments of the invention can be incorporated in cylindrical PV devices.

PV devices of embodiments of the invention can have various uses. For example, PV devices of embodiments of the invention can be used in solar cell arrays in, e.g., solar farms. As another example, PV cell of embodiments of the invention can be used in PV devices disposed on the rooftops of cars. Such devices can provide power to electric or hybrid (gas-electric) vehicles.

### Energy Diagrams

Energy diagrams of PV devices with and without the charge-blocking layer of preferable embodiments of the invention can illustrate the benefits that can be derived from PV devices having the charge-blocking layer.

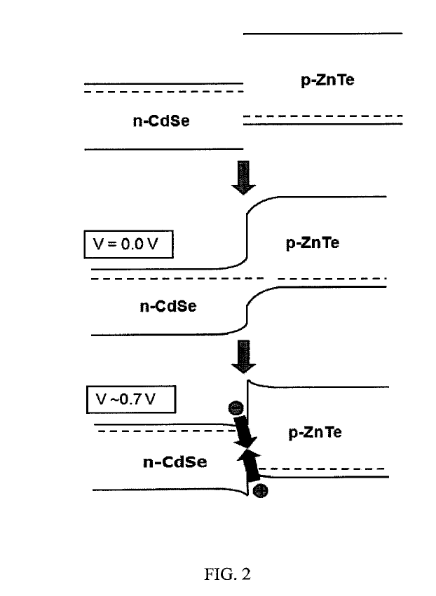

FIG. 2 shows energy band diagrams for a PV device without a charge-blocking layer. The energy band diagrams are directed to a PV device having an n-type CdSe overlying a p-type ZnTe layer; there is no charge-blocking layer between the n-type CdSe layer and the p-type ZnTe layer. The top diagram in FIG. 2 shows the relative band alignments for the two materials; the middle diagram shows the device at zero bias (voltage); and the bottom diagram shows the device at forward bias when exposed to sunlight. Before the PV device can reach a 1.2 V bias, which might be desired for ideal device performance, electron and hole accumulation can start to occur at the CdSe/ZnTe interface. With these high levels of carrier concentration at a heterojunction interface, high recombination currents can be triggered, leading to a decrease in device performance (or efficiency).

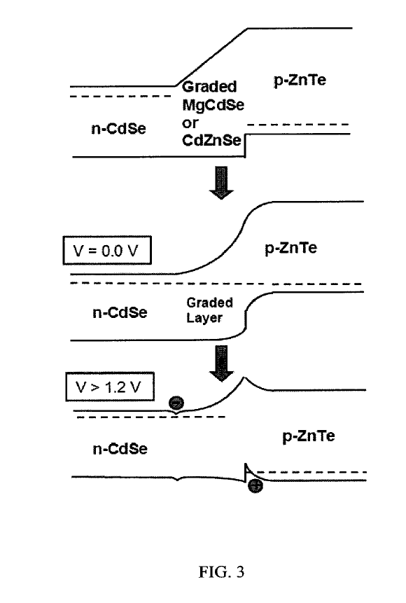

With reference to FIG. 3, the addition of a graded blocking layer results in the spatial separation of regions (also “charge accumulation regions” herein) of electron and holes, leading to improved device performance. The band diagrams of FIG. 3 are directed to a device comprising an n-type CdSe layer, a charge-blocking layer, and a p-type ZnTe layer. In one embodiment, the charge-blocking layer is formed of CdZnSe and compositionally graded (also “graded” herein) in Cd and Zn, i.e., CdₓZn₁₋ₓSe, wherein ‘x’ is a number between 0 and 1. In another embodiment, the charge-blocking layer is formed of CdMgSe and graded in Mg and Cd, i.e., CdₓMg₁₋ₓSe, wherein ‘x’ is a number between 0 and 1. The top plot of FIG. 3 shows a representative example for the relative band alignments prior to charge redistribution. The grading can be engineered such that there is a smooth composition change at the interface between the n-type semiconductor layer (e.g., n-type CdSe) and the graded blocking layer. Grading can be accomplished by an increasing amount of either Zn or Mg in going from the n-CdSe side of the device to the p-ZnTe side of the device. The conduction band edge and band gap can be gradually increased as the ZnTe/graded layer interface is approached. The bottom plot of FIG. 2 shows the band diagram and the desired effect of spatial separation of the regions of charge accumulation at a 1.2 V forward bias.

In embodiments of the invention, a semiconductor heterojunction photovoltaic solar cell can be formed with a blocking layer, wherein the blocking layer is used to (i) spatially separate electrons and holes to significantly reduce interfacial recombination; and/or (ii) prevent early turn-on of the device in order to increase the operating voltage of the device. These two functions can significantly improve the efficiency of a solar cell incorporating a semiconductor heterojunction of embodiments of the invention. These functions can be also achieved by engineering the blocking layer in accordance with the invention. Moreover, the blocking layer can be engineered or designed to satisfy or meet the following conditions: (i) the blocking layer can block a majority of carrier transport at its two ends (the blocking layer band offsets to the adjacent semiconductors can take the form of either an abrupt band offset or a graded band offset); and/or (ii) the blocking layer can sufficiently provide for the free flow of minority carriers in order for the photo-generated current and power to be effectively extracted from the device.

Alternative embodiments of the invention can be used in a stand-alone single junction solar cell. The invention can also be used in the upper or lower cell in a multi-junction solar cell structure (e.g., tandem junction, or three or more junctions). The invention can be used as the upper or lower cell in a two terminal, three terminal, or four terminal multi junction solar devices.

### EXAMPLES

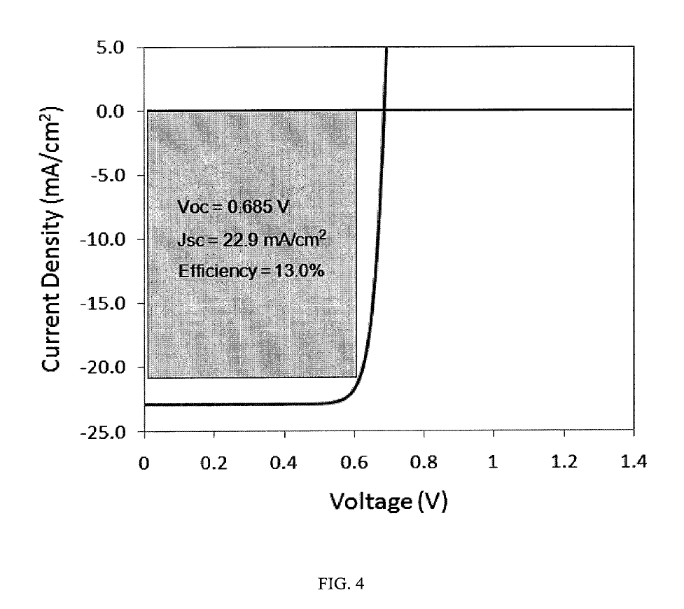

FIGS. 4-10 show plots from solar cell capacitance simulator (“SCAPS”) simulations, in accordance with embodiments of the invention.

FIG. 4 shows the current-voltage (IV) plots for a PV device formed of an n-type CdSe layer overlying a p-type ZnTe layer (also “baseline case” herein). The device of FIG. 4 does not have a charge-blocking layer. As can be seen in the plot, the current densities start to increase at about 0.6 V. At about 0.65 V, the device current flow is in the forward bias direction. The PV device of FIG. 4 had a Jsc of about 22.9 mA/cm², a voltage open circuit (“Voc”) of about 0.69 V, and an efficiency of about 13.0%.

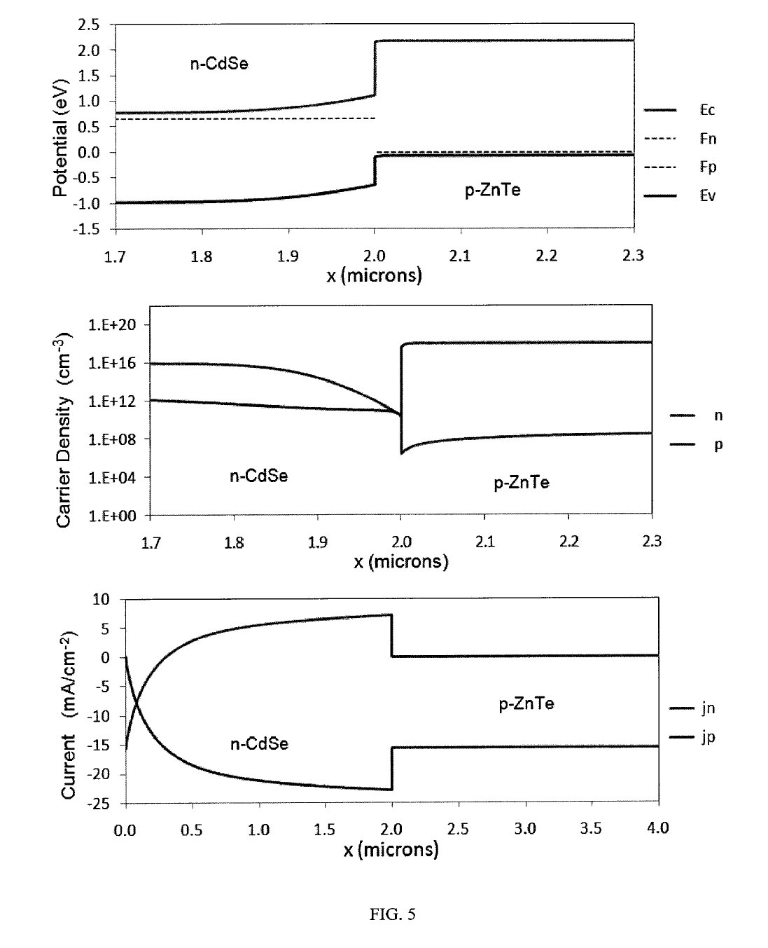

FIG. 5 shows an energy band diagram (top), carrier density profile (middle) and current density profile (bottom) for a baseline n-CdSe/p-ZnTe device at 0.65V forward bias. At this voltage, the conduction and valence bands are approaching the flat band conditions. While both the n-CdSe and p-ZnTe layers remain slightly depleted at the interface between the two materials, the product of the hole and electron concentrations reaches a peak at this interface. Recalling that the slope of the current density profiles are proportional to the recombination rate, it can be seen from the sharp step function shifts in this plot that the high combined concentration of holes and electrons at the interface is resulting in significant interfacial recombination. This recombination is responsible for the low Voc observed in the simulation results and provides further support for explanations of results from earlier experiments within this material system.

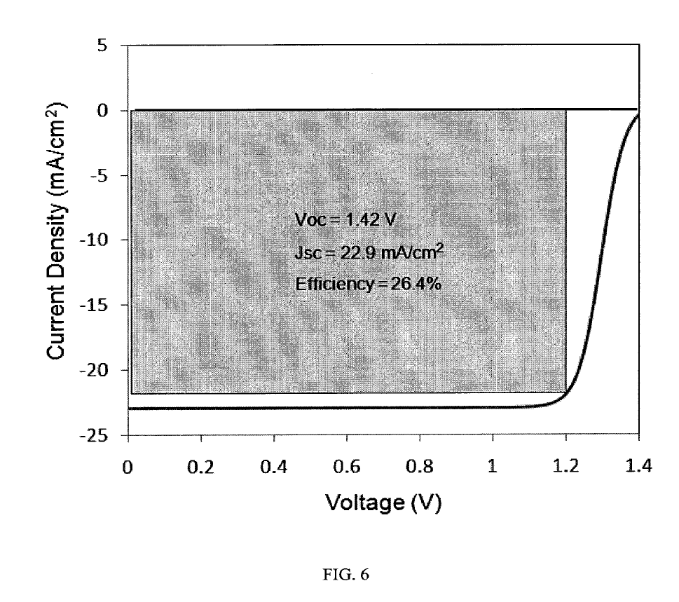

FIG. 6 shows an IV curve for a PV device comprising an n-CdSe layer, a graded charge-blocking layer (CdZnSe), and a p-type ZnTe layer. The turn-on voltage for the device is significantly higher than the turn-on voltage for the device in the baseline case. The PV device of FIG. 6 had a Voc of about 1.4V, a Jsc of about 22.9 mA/cm², and a final efficiency of greater than about 26%. With these results, there was an improvement in overall PV device performance in relation to the baseline case.

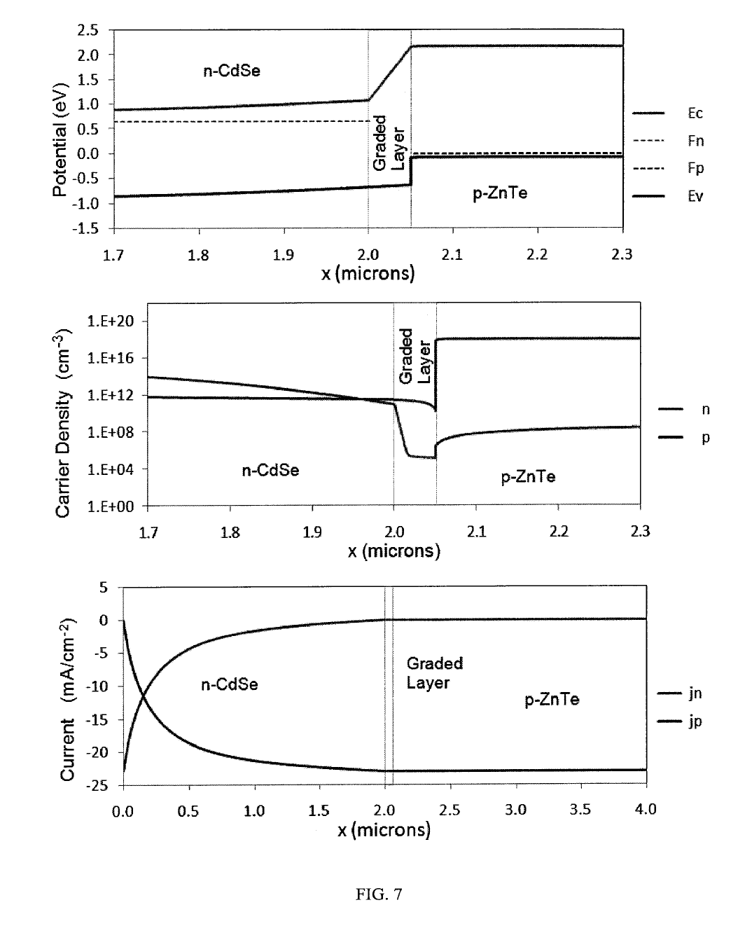

FIG. 7 shows energy band diagram (top, showing conduction and valence band plots), carrier density profile (middle) and current density profile (bottom) for a PV device having an n-CdSe layer, a graded charge-blocking layer, and a p-ZnTe layer. The device was simulated at 0.65V forward bias. To emulate the graded charge-blocking layer, five layers with incrementally increasing band gaps were used. At 0.65 V forward bias, the baseline device was already approaching forward current flow. As with the baseline device, the band diagram shows nearly flat band type conditions. However, examining the charge density profiles, the electron and hole concentrations decreased sharply at either end of the graded blocking layer, resulting in substantially no spatial overlap of the regions of high electron and hole concentration. Similarly, the current density profiles do not show step function changes that are indicative of elevated interfacial recombination. As a result, current flow remains in the reverse bias direction, therefore resulting in higher efficiency.

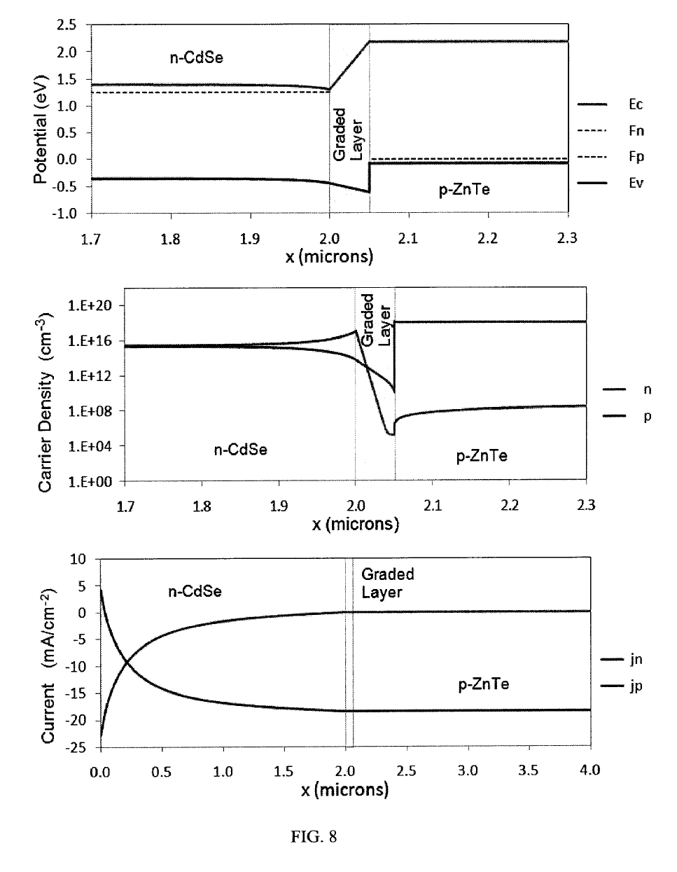

FIG. 8 shows energy band diagram (top, showing conduction and valence band plots), carrier density profile (middle) and current density profile (bottom) for a PV device having an n-CdSe layer, a graded charge-blocking layer, and a p-ZnTe layer. The device was simulated at 1.25V forward bias. At this bias the device is beyond flat band conditions. The hole and electron concentration profile plots (middle) show carrier accumulation at the two interfaces—i.e., the interface between the n-CdSe layer and charge-blocking layer, and the interface between the p-ZnTe layer and the charge-blocking layer—to the graded blocking layer. Even though the carrier concentrations are high, the regions of high concentration advantageously remain spatially separated. At 1.25 V forward bias there is substantially little interfacial recombination.

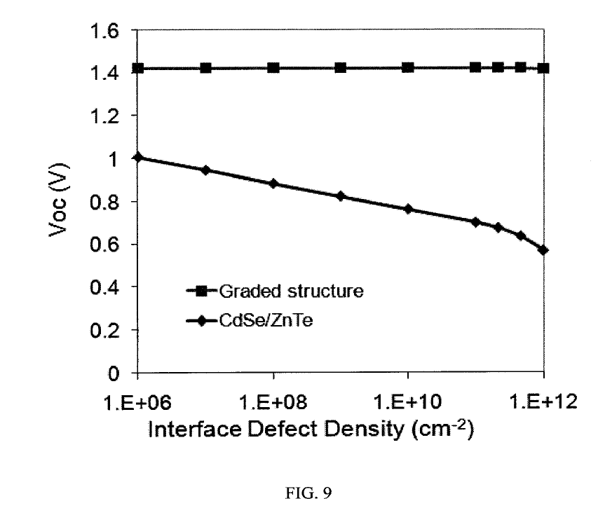

FIG. 9 shows SCAPS simulations results of Voc as a function of interface defect density (interface between the ZnTe layer and the charge-blocking layer) for a standard CdSe/ZnTe device (bottom plot, data points marked by diamonds) and a device incorporating the graded blocking layer (top plot, data points marked by boxes). The incorporation of the blocking layer can enable a significant improvement in device Voc at realistic interface defect densities of about 1×10¹¹ cm⁻². Voc remained in the 1.4 V range, as compared to a significant drop in Voc levels for a PV device not incorporating the blocking layer.

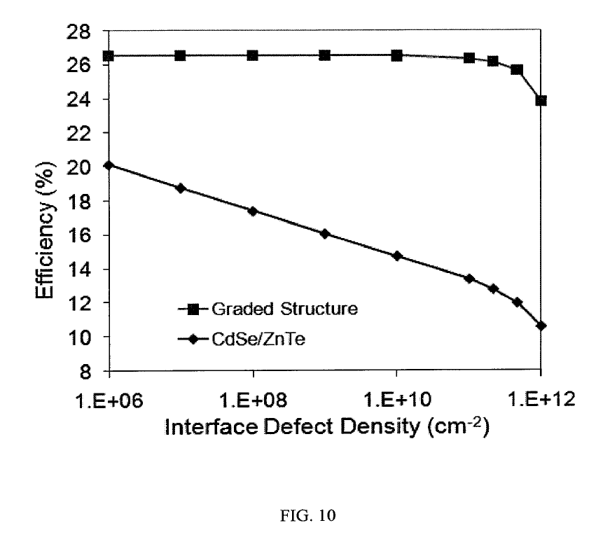

FIG. 10 shows PV cell efficiency as a function of interface defect density (interface between the ZnTe layer and the charge-blocking layer) for a standard CdSe/ZnTe device (bottom plot, data points marked by diamonds) and a device incorporating the graded blocking layer (top plot, data points marked by boxes). At interface defect densities of about 1×10¹¹ cm⁻² efficiencies greater than about 20% were observed for the device having the charge-blocking layer for; at about the same defect density, the device lacking the charge-blocking layer had a defect density of about 10%. FIG. 10 shows that the graded blocking layer can render the PV device relatively insensitive to the density of defects at the interface between the ZnTe layer and the graded charge-blocking layer.

It should be understood from the foregoing that, while particular implementations have been illustrated and described, various modifications can be made thereto and are contemplated herein. It is also not intended that the invention be limited by the specific examples provided within the specification. The concepts of the invention can be applied to other known devices using multi junction and heterojunction structures known in the art such as the following which are entirely incorporated herein by reference: U.S. Pat. No. 5,371,409, entitled, “WIDE BANDGAP SEMICONDUCTOR LIGHT EMITTERS”; U.S. Pat. No. 4,680,422, entitled, “TWO-TERMINAL, THIN FILM, TANDEM SOLAR CELLS”; U.S. patent application Ser. No. 10/551,598, now U.S. Patent Publication No. 2007/0137698, entitled, “MONOLITHIC PHOTOVOLTAIC ENERGY CONVERSION DEVICE”; M. W. Wang et al., “n-CdSe/p-ZnTe based wide band-gap light emitters: Numerical simulation and design,” J. Appl. Phys. 73 (9).; P. Gashin, A. Focsha, T. Potlog, A. V. Simashkevich, V. Leondar, “n-ZnSe/p-ZnTe/n-CdSe tandem solar cells” Solar Energy Materials and Solar Cells, 46, no. 4 (1997), pg. 323-331; P. Mahawela, S. Jeedigunta, S. Vakkalanka, C. S. Ferekides, D. L. Morel, “Transparent high-performance CdSe thin-film solar cells”, Thin Solid Films 480-481, 2005, pg. 466-470.; and S. Vakkalanka, C. S. Ferekides, D. L. Morel, “Development of ZnSexTe1-x p-type contacts for high efficiency tandem structures,” Thin Solid Films 515 (2007), pg. 6132-6135.

While the invention has been described with reference to the aforementioned specification, the descriptions and illustrations of the preferable embodiments herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents.

What is claimed is:

1. A photovoltaic cell comprising a charge-blocking layer having two or more of cadmium (Cd), magnesium (Mg), selenium (Se), tellurium (Te) and zinc (Zn), the charge-blocking layer disposed between a first layer and a second layer, the first layer comprising Te and one or more of Cd and Zn, and the second layer comprising one or more of Cd and Zn and one or more of Se and sulfur (S), the first layer comprising a p-type chemical dopant and the second layer comprising an n-type chemical dopant.

2. The photovoltaic cell of claim 1, wherein the charge-blocking layer is configured to prevent the recombination of electrons and holes by spatially separating regions of electron accumulation from regions of hole accumulation.

3. A photovoltaic device, comprising:
a first layer comprising tellurium (Te) and one or more of cadmium (Cd) and zinc (Zn);
a second layer over the first layer, the second layer comprising two or more of Cd, magnesium (Mg), selenium (Se), Te and Zn in a compositionally-graded configuration; and
a third layer over the second layer, the third layer comprising one or more of cadmium (Cd) and zinc (Zn) and one or more of Se and sulfur (S).

4. The photovoltaic device of claim 3, wherein the first layer further comprises a p-type chemical dopant.

5. The photovoltaic device of claim 3, wherein the third layer further comprises an n-type chemical dopant.

6. The photovoltaic device of claim 3, wherein the composition of the first layer is ZnTe.

7. The photovoltaic device of claim 3, wherein the composition of the first layer is CdZnTe.

8. The photovoltaic device of claim 3, wherein the composition of the third layer is CdSe.

9. The photovoltaic device of claim 3, wherein the composition of the third layer is CdS.

10. The photovoltaic device of claim 3, wherein the composition of the third layer is CdZnSe.

11. The photovoltaic device of claim 3, wherein the composition of the third layer is CdZnS.

12. The photovoltaic device of claim 3, further comprising a substrate below the first layer.

13. The photovoltaic device of claim 3, further comprising a substrate above the third layer.

14. The photovoltaic device of claim 3, wherein the second layer comprises Cd, Zn and Se, wherein Cd and Zn are compositionally graded from a first interface to a second interface of the second layer.

15. The photovoltaic device of claim 3, wherein the second layer comprises Cd, Mg and Se, wherein Cd and Mg are compositionally graded from a first interface to a second interface of the second layer.

16. The photovoltaic device of claim 3, wherein the second layer is configured to prevent the recombination of electrons and holes formed upon exposure of the photovoltaic device to light.

17. A photovoltaic cell comprising a charge-blocking layer between a first layer and a second layer, the first layer being compositionally different from the second layer, wherein the first layer is doped p-type and the second layer is doped n-type, and wherein the charge-blocking layer is configured to prevent the recombination of electrons and holes by spatially separating regions of electron accumulation from regions of hole accumulation.

18. A method for forming a photovoltaic device, comprising:
forming a first layer comprising tellurium (Te) and one or more of cadmium (Cd) and zinc (Zn);
forming a second layer comprising two or more of Cd, magnesium (Mg), selenium (Se), Te and Zn in a compositionally-graded configuration; and
forming a third layer comprising one or more of Cd and Zn and one or more of Se and Sulfur (S).

19. The method of claim 18, wherein the first layer is doped with a p-type chemical dopant.

20. The method of claim 18, wherein the third layer is doped with an n-type chemical dopant.

21. The method of claim 18, wherein the first layer is adjacent the second layer.

22. The method of claim 18, wherein forming the first layer comes before forming the third layer.

23. The method of claim 18, wherein forming the first layer comes after forming the third layer.

24. A photovoltaic array comprising the photovoltaic device of claim 1.

25. A photovoltaic array comprising the photovoltaic cell of claim 17.
